(19) United States
(12) Patent Application Publication
(10) Pub. No.: US 2026/0129909 A1
(43) Pub. Date: May 7, 2026

(54) TRANSISTOR DEVICE WITH SELECTIVE THICK GATE DIELECTRIC AND METHOD

(71) Applicant: Micron Technology, Inc., Boise, ID (US)

(72) Inventors: Mandar Suresh Bhoir, Boise, ID (US); Salil Shashikant Mujumdar, Nanakaramguda (IN); Uma Sharma, Boise, ID (US)

(21) Appl. No.: 19/377,920

(22) Filed: Nov. 3, 2025

Related U.S. Application Data
(60) Provisional application No. 63/717,015, filed on Nov. 6, 2024.

(51) Int. Cl. H10D 30/67; H10B 12/00

(52) U.S. Cl. CPC H10D 30/6736; H10B 12/05; H10B 12/315; H10B 12/488; H10D 30/6728; H10D 30/6735; H10D 30/6757

(57) ABSTRACT

Apparatus and methods are disclosed, including transistors, semiconductor devices and systems. Example semiconductor devices and methods include gate dielectrics in transistor devices with different thicknesses. Apparatus and methods are disclosed using a dopant to vary growth of gate dielectrics at desired locations within a semiconductor device.

### PRIORITY APPLICATION

This application claims the benefit of priority to U.S. Provisional Application Ser. No. 63/717,015, filed Nov. 6, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates a top view of a portion of a memory device in accordance with some example embodiments.

FIG. 2B illustrates an isometric view of the portion from FIG. 2 in accordance with some example embodiments.

FIG. 3 illustrates a cross section view of a portion of a memory device in accordance with some example embodiments.

FIG. 4A illustrates another cross section view of a portion of a memory device in accordance with some example embodiments.

FIG. 4B illustrates another cross section view of a portion of a memory device in accordance with some example embodiments.

FIG. 5 illustrates a plot of gate dielectric thicknesses versus dopant dose in accordance with some example embodiments.

FIG. 6 illustrates an example method flow diagram in accordance with other example embodiments.

FIG. 7 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

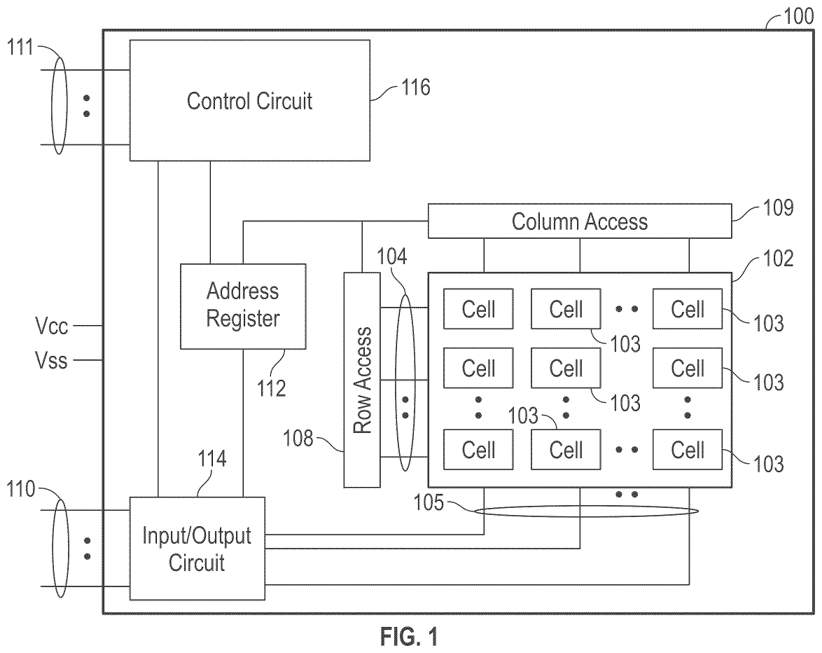

FIG. 1 shows a block diagram of an apparatus in the form of a memory device 100, according to an embodiment of the invention. Memory device 100 can include transistors with gate oxide configurations that have different thicknesses as described in more detail below. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

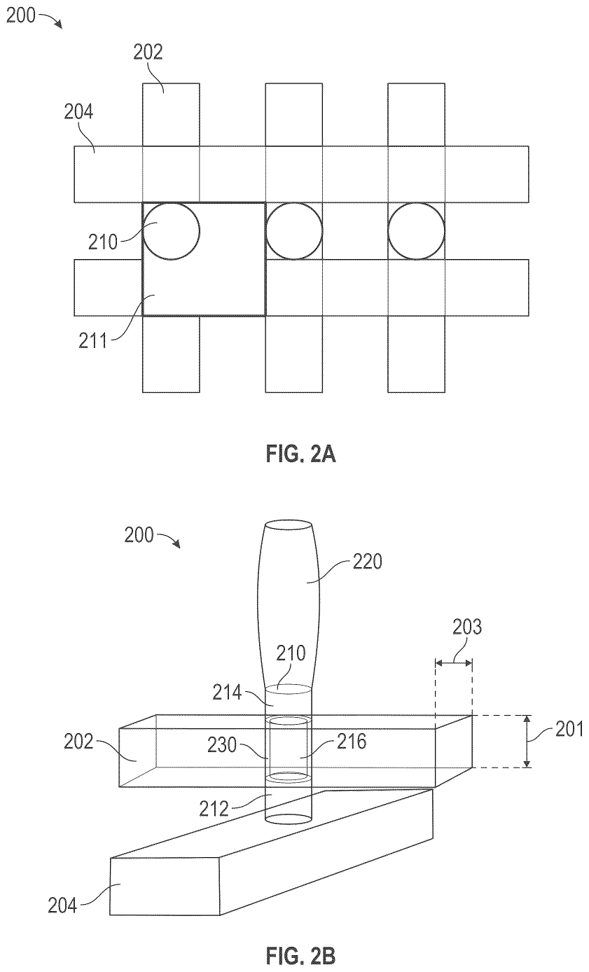

Memory cells 103 and other circuits 114, 116, etc. may include transistors and utilize methods as described in more detail in FIGS. 2-7. In one example, memory arrays 102 include NAND storage array, and peripheral circuits such as circuits 114, 116, 108, 109, etc. may include transistors as described in more detail in FIGS. 2-7. One example of a peripheral circuit that utilizes transistors as described includes a string driver circuit, although the invention is not so limited.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIGS. 2A and 2B show a memory device 200 according to selected examples. In the example shown, the memory device 200 includes one or more 4F² memory cells 211. 4F² refers to a memory cell in which dimensions of a given cell real estate area are 2F on each side (for example, each side of the square denoting memory cell 211). The cell area is 2F×2F, which equals 4F². The term “F” refers to a minimum lithographic feature dimension, and is determined by a wavelength of a beam used to form a given feature. In one example, the memory cells 211 include thin film transistors. A number of transmission lines 202 and a number of data lines 204 are shown. A body region 210 is included between the number of transmission lines 202 and the number of data lines 204. In one example, the number of transmission lines 202 include wordlines. In one example, the number of data lines 204 include bitlines.

The body region 210 is shown passing through a thickness 201 of a transmission line 202 within a width 203 of the transmission line 202. A channel region 216 is shown, and a gate dielectric 230 surrounding the body region 210 and laterally separating the body region 210 from the transmission line 202. A first source/drain region 212 and a second source/drain region 214 are shown, with the channel region 216 located between the source/drain regions 212, 214. In one example, the source/drain regions 212, 214 are doped N-type, and the channel region is doped P-type. In another example, the source/drain regions 212, 214 are doped P-type, and the channel region is doped N-type. A capacitor 220 is shown at an upper end of the body region. In one example, the capacitor 220 includes a storage capacitor to store memory data.

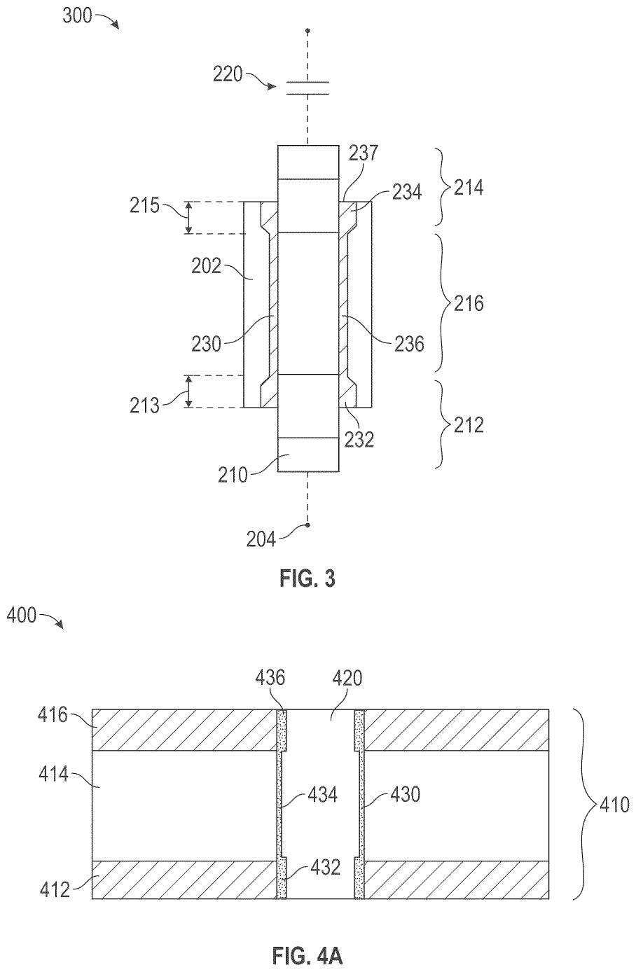

A technical challenge may occur in configurations such as FIGS. 2A and 2B where degraded electrical performance at corners where the top or bottom of the transmission line 202 is adjacent to the body region 210. FIG. 3 shows an example of a configuration that addresses this and other concerns.

FIG. 3 shows a cross section view of a portion 300 of the memory device 200 from FIGS. 2A and 2B. The body region 210 is shown, along with a section of the transmission line 202. The gate dielectric 230 is shown laterally separating the body region 210 from the transmission line 202. The first source/drain region 212 and the second source/drain region 214 are shown with the channel region 216 coupled therebetween. The data line 204 and the capacitor 220 are shown in electrical schematic format.

In the example of FIG. 3, the first source/drain region 212 and the second source/drain region 214 are at least partially located within the thickness of the transmission line 202. Stated another way, the first source/drain region 212 penetrates past a bottom edge of the transmission line 202 to a distance 213. Similarly, the second source/drain region 214 penetrates past a top edge of the transmission line 202 to a distance 215.

In the example shown, the transmission line 202 serves as a wordline, and an applied charge serves as a gate, that selectively activates the channel region 216 and provides a transistor function. As noted above, at corners 237, there is a need for protecting against degrading electrical performance. An example of a condition that degrades electrical performance includes gate induced drain leakage.

In one example, the oxide 230 over the source/drain overlapped regions 212, 214 is responsible for an increasing gate-electric field in the source/drain overlapped regions 212, 214. In one example of bias-conditions with the transmission line 202 (gate) in an off-state (Vg<=0) and source/drain regions 212, 214 at higher potential (Vdd), a large amount of gate-induced drain leakage (GIDL) is generated. For an n-type thin film transistor (TFT), electrons generated due to a GIDL process are swept away into source/drain regions 212, 214 while holes move in the TFT's channel region 216 (body) region (The charge carriers are opposite in a p-type TFT).

In this example, as this device doesn't have any body contact (the channel region 216 is electrically floating), those holes accumulate in the channel region 216 lowering the TFT threshold voltage and thereby increasing leakage from cell to bit line or vice-versa. This phenomena is known as floating body effect (FBE). The resultant is loss of cell-charge and degraded refresh time (worse DRAM performance).

To address this concern, the gate dielectric 230 gate dielectric varies in thickness with thicker regions adjacent to the top surface and the bottom surface of the transmission line 202. As shown in FIG. 3, the gate dielectric 230 includes a first thicker region 232 adjacent to a bottom surface of the transmission line 202, and a second thicker region 234 adjacent to a top surface of the transmission line 202.

The thicker regions 232, 234 provide increased protection to the memory device 200 by reducing the degraded electric performance at corners 237. Concurrently, a thinner middle region 236 is included adjacent to the channel region 216 that provides improved switching characteristics of the transistor compared to a thicker gate dielectric 230 across all regions of the gate dielectric 230.

Formation of the thicker regions 232, 234 as compared to the middle region 236 is accomplished using a dopant that promotes growth of the gate dielectric. In one example, the gate dielectric 230 includes a gate oxide. In one example, the gate dielectric 230 includes silicon oxide. In one example, the gate dielectric includes other oxide, such as transition metal oxides. Examples include tantalum oxide, hafnium oxide, lanthanum oxide, etc.

In one example, the dopant that promotes growth of the gate dielectric includes fluorine. In one example, the dopant that promotes growth of the gate dielectric includes argon. In one example, the dopant that promotes growth of the gate dielectric includes deuterium. In one example, a plurality of dopants are utilized to promote growth of the gate dielectric. In one example, instead of a dopant that promotes growth of a gate dielectric, a dopant is included that retards growth of a gate dielectric in regions where a thinner gate dielectric is desired. This yields a similar effect of a gate dielectric with varying thickness.

Several methods of incorporating a dopant are possible, each having different advantages. In one example, a dopant that promotes growth of the gate dielectric is implanted in a base material by ion implantation. In one example, the base material is formed with the dopant incorporated in the bulk of the base material. In one example, a dopant that promotes growth of the gate dielectric is chemically or physically deposited within a carrier material on a surface of a base material, then annealed or otherwise driven into a surface of the base material for oxidizing. One example of a carrier material includes polysilicon.

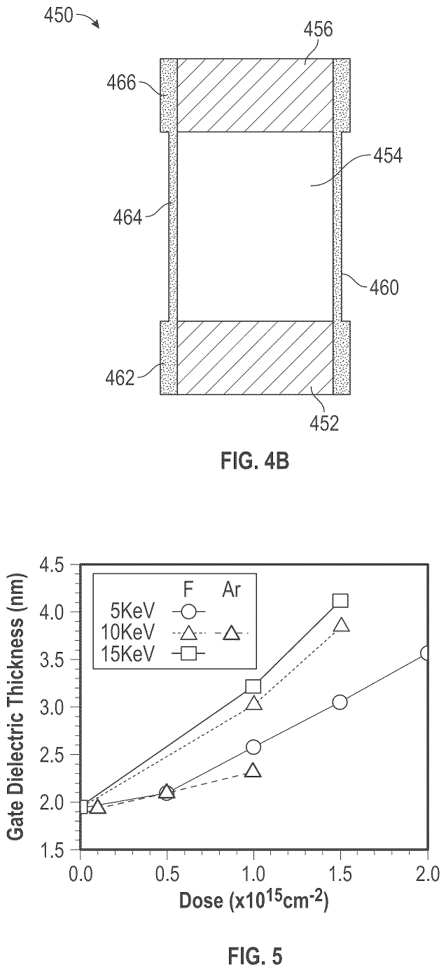

FIG. 4A shows one example of a gate dielectric 430 included in a memory device 400 formed by oxidizing within a hole 420, or opening in a base material such as a wordline 410 as described in examples above. In the example of FIG. 4A, the wordline 410 is formed in multiple layers. A first layer 412 includes a dopant that promotes growth of a gate dielectric. A second layer 414 includes less, or none of a dopant that promotes growth of a gate dielectric, and a third layer 416 again includes a dopant that promotes growth of a gate dielectric. In one example, a dopant that promotes growth of a gate dielectric is absent from the second layer 414, although the invention is not so limited. Different concentrations of the dopant that promotes growth of a gate dielectric are all that is needed to form differences in gate dielectric thickness as described.

In FIG. 4A, after oxidizing within the hole 420, a first portion 432 of the grown oxide is thicker than a second portion 434 of the grown oxide. Similarly, a third portion 436 of the grown oxide is thicker than the second portion 434 of the grown oxide. As noted, the differences in thickness between the portions 432, 434, and 436 are due to different concentrations of dopant in the layers 412, 414, and 416 that are oxidized.

After growth of the gate dielectric 430, a detectable amount of the dopant will be present in the various portions of the gate dielectric 430, or adjacent to the gate dielectric 430. For example, in 4A, if fluorine is used as the dopant to promote oxide growth, the thicker top and bottom first portion 432 and third portion 436 will include a detectable amount of fluorine.

After growth of the gate dielectric 430 as shown in FIG. 4A, further processing is performed to form a body region within the hole 420 similar to body region 210 as described above. The formed body region will include source/drain regions and a channel region as described.

FIG. 4B shows another example method of formation and resulting structures. A body region 450 is shown. A bottom portion 452 and a top portion 456 are doped by a suitable method such as ion implantation, or diffusing a dopant from a sacrificial material that is later removed. One example of a sacrificial material includes doped polysilicon. In one example, the bottom portion 452 and the top portion of the body region include source/drain regions, while a middle portion 454 includes a channel. The middle portion 454 is doped less or is without a dopant that promotes oxide growth.

A gate dielectric 460 is then grown over the body region 450. Due to the different concentrations of the dopant in the body region, the gate dielectric 460 grows thicker in a first portion 462 and a third portion 466 than in a middle second portion 464. After growth of the gate dielectric 460 as shown in FIG. 4B, further processing is performed to form a wordline around the body region 450 similar to the wordline 202 as described above.

FIG. 5 shows a graph of a non-limiting selection of possible dopants and a change in thickness of a grown oxide in response to larger ion implantation doses and implant energies of the dopant. Argon and fluorine are shown in the graph. As can be seen, larger doses of fluorine result in larger thicknesses of oxide growth.

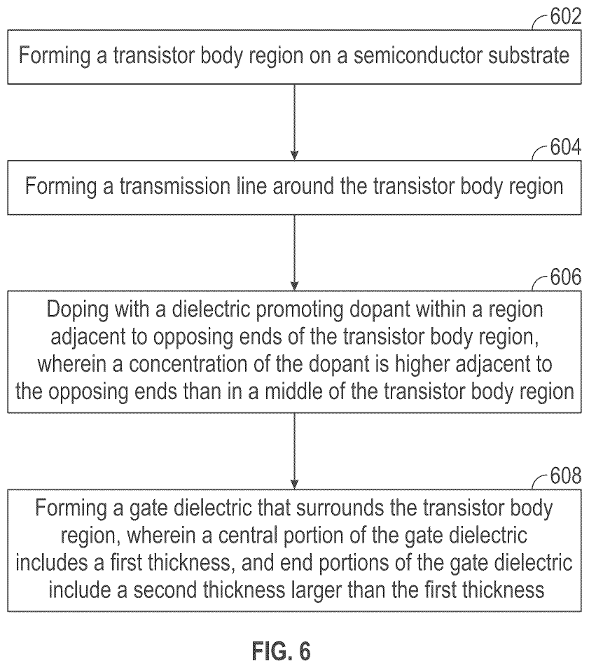

FIG. 6 shows a flow diagram of one example method of manufacture. In operation 602, a transistor body region is formed on a semiconductor substrate. In operation 604, a transmission line is formed around the transistor body region. In operation 606, a dielectric promoting dopant is introduced within a region adjacent to opposing ends of the transistor body region. A concentration of the dopant is higher adjacent to the opposing ends than in a middle of the transistor body region. In operation 608, a gate dielectric is formed that surrounds the transistor body region. The gate dielectric includes a central portion of the gate dielectric includes a first thickness, and end portions of the gate dielectric include a second thickness larger than the first thickness.

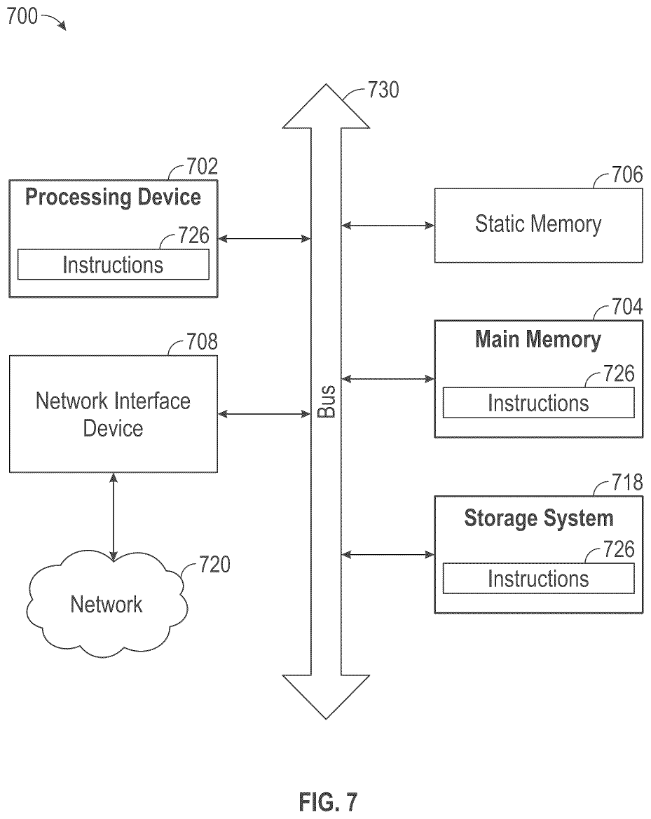

FIG. 7 illustrates a block diagram of an example machine (e.g., a host system) 900 which may include one or more transistors, memory devices and/or memory systems with gate dielectrics as described above. As discussed above, machine 700 may benefit from enhanced memory performance from use of one or more of the described transistor structures and/or memory systems, facilitating improved performance of machine 700 (as for many such machines or systems, efficient reading and writing of memory can facilitate improved performance of a processor or other components that machine, as described further below.

In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 700 may include a processing device 702 (e.g., a hardware processor, a central processing unit (CPU), a graphics processing unit (GPU), a hardware processor core, or any combination thereof, etc.), a main memory 704 (e.g., read-only memory (ROM), dynamic random-access memory (DRAM) such as synchronous DRAM (SDRAM) or Rambus DRAM (RDRAM), etc.), a static memory 706 (e.g., static random-access memory (SRAM), etc.), and a storage system 718, some or all of which may communicate with each other via a communication interface (e.g., a bus) 730. In one example, the main memory 704 includes one or more memory devices as described in examples above.

The processing device 702 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 702 can also be one or more special-purpose processing devices such as an application specific integrated circuit (ASIC), a field programmable gate array (FPGA), a digital signal processor (DSP), network processor, or the like. The processing device 702 can be configured to execute instructions 726 for performing the operations and steps discussed herein. The computer system 700 can further include a network interface device 708 to communicate over a network 720.

The storage system 718 can include a machine-readable storage medium (also known as a computer-readable medium) on which is stored one or more sets of instructions 726 or software embodying any one or more of the methodologies or functions described herein. The instructions 726 can also reside, completely or at least partially, within the main memory 704 or within the processing device 702 during execution thereof by the computer system 700, the main memory 704 and the processing device 702 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 700 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 700 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 726 (e.g., software, programs, an operating system (OS), etc.) or other data are stored on the storage system 718 can be accessed by the main memory 704 for use by the processing device 702. The main memory 704 (e.g., DRAM) is typically fast, but volatile, and thus a different type of storage than the storage system 718 (e.g., an SSD), which is suitable for long-term storage, including while in an “off” condition. The instructions 726 or data in use by a user or the machine 700 are typically loaded in the main memory 704 for use by the processing device 702. When the main memory 704 is full, virtual space from the storage system 718 can be allocated to supplement the main memory 704; however, because the storage system 718 device is typically slower than the main memory 704, and write speeds are typically at least twice as slow as read speeds, use of virtual memory can greatly reduce user experience due to storage system latency (in contrast to the main memory 704, e.g., DRAM). Further, use of the storage system 718 for virtual memory can greatly reduce the usable lifespan of the storage system 718.

The instructions 726 may further be transmitted or received over a network 720 using a transmission medium via the network interface device 708 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 708 may include one or more physical jacks (e.g., Ethernet, coaxial, or phone jacks) or one or more antennas to connect to the network 720. In an example, the network interface device 708 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 700, and includes digital or analog communications signals or other intangible medium to facilitate communication of such software.

1The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. 1Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:
Example 1. A semiconductor memory device, comprising: a transmission line, having a width and a thickness between a top surface and a bottom surface; a body region passing through the thickness of the transmission line within the width of the transmission line, wherein the body region includes a first source/drain region and a second source/drain region separated by a channel region; and a gate dielectric surrounding the body region and laterally separating the body region from the transmission line, wherein the gate dielectric varies in thickness with thicker regions adjacent to the top surface and the bottom surface.
Example 2. The semiconductor memory device of example 1, wherein the first source/drain region and the second source/drain region are doped N-type, and the channel region is doped P-type.
Example 3. The semiconductor memory device of example 1, wherein the first source/drain region and the second source/drain region are doped P-type, and the channel region is doped N-type.
Example 4. The semiconductor memory device of example 1, wherein the gate dielectric includes an oxide material.
Example 5. The semiconductor memory device of example 1, wherein a memory cell of the semiconductor memory device includes a 4F2 form factor memory cell.
Example 6. The semiconductor memory device of example 1, further including a storage capacitor coupled to the second source/drain region.
Example 7. The semiconductor memory device of example 1, wherein the first source/drain region and the second source/drain region are at least partially located within the thickness of the transmission line
Example 8. The semiconductor memory device of example 1, wherein the transmission line includes a wordline.
Example 9. A semiconductor memory device, comprising: a transmission line, having a width and a thickness between a top surface and a bottom surface; a body region passing through the thickness of the transmission line within the width of the transmission line, wherein the body region includes a first source/drain region and a second source/drain region separated by a channel region; a gate oxide surrounding the body region and laterally separating the body region from the transmission line, wherein the gate oxide varies in thickness with thicker regions adjacent to the top surface and the bottom surface; and an oxide promoting dopant within the gate oxide.
Example 10. The semiconductor memory device of example 9, wherein the oxide promoting dopant includes fluorine.
Example 11. The semiconductor memory device of example 9, wherein the oxide promoting dopant includes argon.
Example 12. The semiconductor memory device of example 9, wherein the oxide promoting dopant includes deuterium.
Example 13. The semiconductor memory device of example 9, wherein the gate oxide includes silicon oxide.
Example 14. The semiconductor memory device of example 9, wherein the gate oxide includes a transition metal oxide.
Example 15. A method of forming a semiconductor device, comprising: forming a transistor body region on a semiconductor substrate; forming a transmission line around the transistor body region; doping with a dielectric promoting dopant within a region adjacent to opposing ends of the transistor body region, wherein a concentration of the dopant is higher adjacent to the opposing ends than in a middle of the transistor body region; forming a gate dielectric that surrounds the transistor body region, wherein; a central portion of the gate dielectric includes a first thickness; and end portions of the gate dielectric include a second thickness larger than the first thickness.
Example 16. The method of example 15, wherein doping with a dielectric promoting dopant includes ion implantation of the dielectric promoting dopant.
Example 17. The method of example 15, wherein doping with a dielectric promoting dopant includes depositing a doped material.
Example 18. The method of example 15, wherein forming the transmission line includes forming a transmission line that includes polysilicon.
Example 19. The method of example 18, wherein forming the transmission line includes forming multiple layers, wherein a top transmission line layer and a bottom transmission line layer are doped.
Example 20. The method of example 19, wherein the transmission line is formed before the transistor body region, and wherein forming the gate dielectric includes oxidizing within an opening in the transmission line before filling the opening with the transistor body region.
Example 21. The method of example 15, wherein the transistor body region is formed before the transmission line, and wherein forming the gate dielectric includes oxidizing the transistor body region before forming the transmission line around the gate dielectric.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed IS:

1. A semiconductor memory device, comprising:
a transmission line, having a width and a thickness between a top surface and a bottom surface;
a body region passing through the thickness of the transmission line within the width of the transmission line, wherein the body region includes a first source/drain region and a second source/drain region separated by a channel region; and
a gate dielectric surrounding the body region and laterally separating the body region from the transmission line, wherein the gate dielectric varies in thickness with thicker regions adjacent to the top surface and the bottom surface.

2. The semiconductor memory device of claim 1, wherein the first source/drain region and the second source/drain region are doped N-type, and the channel region is doped P-type.

3. The semiconductor memory device of claim 1, wherein the first source/drain region and the second source/drain region are doped P-type, and the channel region is doped N-type.

4. The semiconductor memory device of claim 1, wherein the gate dielectric includes an oxide material.

5. The semiconductor memory device of claim 1, wherein a memory cell of the semiconductor memory device includes a 4F² form factor memory cell.

6. The semiconductor memory device of claim 1, further including a storage capacitor coupled to the second source/drain region.

7. The semiconductor memory device of claim 1, wherein the first source/drain region and the second source/drain region are at least partially located within the thickness of the transmission line

8. The semiconductor memory device of claim 1, wherein the transmission line includes a wordline.

9. A semiconductor memory device, comprising:
a transmission line, having a width and a thickness between a top surface and a bottom surface;
a body region passing through the thickness of the transmission line within the width of the transmission line, wherein the body region includes a first source/drain region and a second source/drain region separated by a channel region;
a gate oxide surrounding the body region and laterally separating the body region from the transmission line, wherein the gate oxide varies in thickness with thicker regions adjacent to the top surface and the bottom surface; and
an oxide promoting dopant within the gate oxide.

10. The semiconductor memory device of claim 9, wherein the oxide promoting dopant includes fluorine.

11. The semiconductor memory device of claim 9, wherein the oxide promoting dopant includes argon.

12. The semiconductor memory device of claim 9, wherein the oxide promoting dopant includes deuterium.

13. The semiconductor memory device of claim 9, wherein the gate oxide includes silicon oxide.

14. The semiconductor memory device of claim 9, wherein the gate oxide includes a transition metal oxide.

15. A method of forming a semiconductor device, comprising:
forming a transistor body region on a semiconductor substrate;
forming a transmission line around the transistor body region;
doping with a dielectric promoting dopant within a region adjacent to opposing ends of the transistor body region, wherein a concentration of the dopant is higher adjacent to the opposing ends than in a middle of the transistor body region;
forming a gate dielectric that surrounds the transistor body region, wherein;
a central portion of the gate dielectric includes a first thickness; and
end portions of the gate dielectric include a second thickness larger than the first thickness.

16. The method of claim 15, wherein doping with a dielectric promoting dopant includes ion implantation of the dielectric promoting dopant.

17. The method of claim 15, wherein doping with a dielectric promoting dopant includes depositing a doped material.

18. The method of claim 15, wherein forming the transmission line includes forming a transmission line that includes polysilicon.

19. The method of claim 18, wherein forming the transmission line includes forming multiple layers, wherein a top transmission line layer and a bottom transmission line layer are doped.

20. The method of claim 19, wherein the transmission line is formed before the transistor body region, and wherein forming the gate dielectric includes oxidizing within an opening in the transmission line before filling the opening with the transistor body region.

21. The method of claim 15, wherein the transistor body region is formed before the transmission line, and wherein forming the gate dielectric includes oxidizing the transistor body region before forming the transmission line around the gate dielectric.
